(19) United States
(12) Patent Application Publication
(10) Pub. No.: US 2008/0063889 A1
(43) Pub. Date: Mar. 13, 2008

(54) Reactive Multilayer Joining WIth Improved Metallization Techniques

(76) Inventors: Alan Duckham, Baltimore, MD (US); Timothy P. Weihs, Baltimore, MD (US); Jesse Newson, Cockeysville, MD (US); Jonathan Levin, Arlington Heights, IL (US); Somasundaram Valliappan, Timonium, MD (US)

Correspondence Address: POLSTER, LIEDER, WOODRUFF & LUCCHESI, 12412 POWERSCOURT DRIVE SUITE 200, ST. LOUIS, MO, 63131-3615, US

(21) Appl. No.: 11/851,003

(22) Filed: Sep. 6, 2007

Related U.S. Application Data
(60) Provisional application No. 60/825,055, filed on Sep. 8, 2006.
(60) Provisional application No. 60/915,823, filed on May 3, 2007.

(51) Int. Cl. B32B 15/00; B23K 1/20; C23C 14/00; B23K 31/02

(52) U.S. Cl. 428/615; 204/192.1; 228/205; 228/208

(57) ABSTRACT

A process and apparatus for the reactive multilayer joining of components utilizing metallization techniques to bond difficult-to-wet materials and temperature sensitive materials to produce joined products.

### CROSS-REFERENCE TO RELATED APPLICATIONS

The present application is a non-provisional of, and claims priority from, U.S. Provisional Application Ser. No. 60/825,055 filed on Sep. 8, 2006, which is herein incorporated by reference.

The present application is a non-provisional of, and claims priority from, U.S. Provisional Application Ser. No. 60/915,823 filed on May 3, 2007, which is herein incorporated by reference.

The present application is related to U.S. patent application Ser. No. 10/761,443 filed Jan. 21, 2004 which, in turn, is a divisional of U.S. patent application Ser. No. 09/846,486, filed on May 1, 2001 (now U.S. Pat. No. 6,736,942) which claimed the benefit of U.S. Provisional Patent Application No. 60/201,292 filed May 2, 2000. Each of the '443, '486, and '292 applications is herein incorporated by reference.

The present application is also related to U.S. patent application Ser. No. 11/393,055 filed Mar. 30, 2006, which is incorporated herein by reference.

### STATEMENT REGARDING FEDERALLY SPONSORED RESEARCH

The United States Government has certain rights in this invention pursuant to contract number W911QX-04-C-0025 with the Army Research Laboratory.

### BACKGROUND OF THE INVENTION

The present invention relates to methods of joining components by reactive multilayer joining with solder or braze, and in particular to methods of such joining which provide enhanced adhesion between the components and the solder or braze, as well as to improved products made by such joining methods.

Reactive multilayer joining processes upon which the present invention improves, are generally described in U.S. Pat. No. 6,736,942 and U.S. Pat. No. 6,991,856, each incorporated herein by reference. Reactive multilayer joining addresses two problems that occur when using conventional soldering and brazing to join component bodies. First, the temperatures required for conventional joining of component bodies can cause significant thermal stresses in the components upon cooling. Second, the temperatures required for conventional joining can cause undesirable changes in the components themselves, such as grain growth or diffusion. Nonetheless, it is often desirable to join components with solder or braze joints due to the properties of the resulting joints, including high thermal and electrical conductivity, strength, avoidance of outgassing, high temperature stability, and others.

Differences in the coefficients of thermal expansion (CTE) between component body materials can limit the use of conventional soldering and brazing processes. In such conventional processes, a large volume of each component body adjacent the bond is heated above the melting temperature of the solder or braze. On cooling, the contraction of the component body with the higher CTE relative to the other component body results in severe residual stresses within the bond and in the components themselves. For example, such stresses generally occur when ceramic plates are bonded to metal plates, and are often a concern when both components are metals or ceramics. The net result is that good quality bonds are limited to small areas. Large area bonds are often of low quality, characterized by debonding, cracking and warping of the components.

An example of products in which bonding is a problem is with targets for vapor deposition. These targets are used in physical vapor deposition systems as the source of atoms to be deposited in coatings onto substrates. Such targets are typically composed of a target plate, comprising material to be vapor deposited, which is bonded to a backing plate (usually copper or another metal) that serves as a physical support. Target plates may be metals, alloys, ceramics, or ceramic composites, and may have surface areas which range from a few square centimeters to thousands of square centimeters. The bond between the target plate and the backing plate must ideally be thermally conductive, be able to withstand temperatures above 100° C., and be able to accommodate or prevent residual stresses.

Conventionally, indium solder or elastomers are used to bond target plates and backing plates, to mitigate the CTE mismatch problems discussed above. However, indium has low strength (tensile strength of 2 MPa) and a very low melting temperature (157° C.). Indium bonds are thus weak and are unable to tolerate even moderate temperatures when in service. Moreover, even with indium solder, residual stresses locked in during conventional bonding can lead to poor bond quality and cracking of ceramic components during service. Elastomer bonds have higher strengths, but they suffer from very low electrical and thermal conductivities. They are also subject to outgassing during service, which can often be problematic when used in vacuum systems.

Conventional solder or braze bonding is very difficult with temperature-sensitive materials. The term temperature-sensitive material refers to a material where a structural physical property changes an appreciable amount when the material is heated. Typical such materials include metals, alloys, ceramics and polymers. The structural physical property changes upon heating and remains changed even upon subsequent cooling. Typical such structural physical properties include microstructural grain size, hardness, yield strength, tensile strength, magnetization, magnetic susceptibility, electrical conductivity, thermal conductivity, optical transmissivity, optical absorptivity, elasticity, chemical structure, and index of refraction. Other structural physical properties include the dimensions or shape of the material specimen. For example, a rolled metal plate may contain considerable residual stress. Upon heating, the plate may bend or warp and remain deformed upon cooling. A material would be regarded as temperature sensitive if upon heating to 200° C. for about 30 minutes one of these physical properties is changed by 10% or more. Particularly noteworthy temperature-sensitive materials include alloys that can be strengthened by cold work or heat treatment such as aluminum alloys (e.g. the 5000 and 6000 series of aluminum alloys) and copper alloys.

Reactive multilayer joining can enable or improve bonding of temperature-sensitive and other materials. As shown in FIG. 1, a reactive composite material (RCM) 14 commonly consists of thousands of alternating nanoscale layers 16 and 18, such as alternating layers of Ni and Al. The layers react exothermically when atomic diffusion between the layers is initiated by an external energy pulse (not shown), and release a rapid burst of heat in a self-propagating reaction. If layers of solder or braze alloy are placed between the RCM and the components, the heat released by the RCM can be harnessed to melt the solder or braze alloy layers as shown in FIG. 2.

By controlling the properties of the RCM, the exact amount of heat released by the RCM can be tuned to ensure there is sufficient heat to melt the solder or braze layers but insufficient heat to raise the temperature of the bulk components significantly above room temperature. The components therefore do not undergo any significant expansion or contraction during the bonding process, thus rendering differences in CTE unimportant. Reactive multilayer joining is thus a room temperature joining method that enables low stress, high quality, metallic bonds between materials with dissimilar CTE's. The low temperatures maintained in the components also prevent diffusion, grain growth, and degradation of properties in temperature-sensitive materials.

Other advantages of reactive multilayer joining include low thermal and electrical resistance in bonds due to the use of solders and brazes with typically high conductivities. Also, solder joints formed by reactive multilayer joining are often stronger than joints formed via reflow of the same solder, due to the finer grain structure created by rapid cooling after reactive multilayer joining.

The length of time over which the fusible layers are liquid during reactive multilayer joining depends strongly on the heat of reaction in the RCM and the thermal properties of the RCM, the fusible layers, and the components. During reactive multilayer joining, the fusible layers are liquid at the interfaces for typically less than about 5 ms. In this short time, wetting and adhesion at two or more interfaces can take place. To improve wetting and adhesion in the short time available during reactive multilayer joining, the surfaces of the components may be prepared in advance. The current invention addresses this wetting and adhesion process.

Gold metallization is a common technique for creating an adhesion layer on many types of materials, including ceramics, composites, and polymers. This technique typically requires plating or vapor deposition (e.g. sputtering) of two to three metal layers, culminating with a thin layer of gold. However, metallization via vapor deposition requires a vacuum chamber and guns large enough to accommodate the components. In addition, the purchase of precious metal targets for metallization of large pieces can be cost-prohibitive. Plating is not feasible for some parts due to geometries or chemical incompatibility with the plating baths. Gold has the added disadvantage that during bonding, some time is required for solder to adhere to the gold and underlayer. This time may be too long for reactive multilayer joining.

Metal components may commonly be “pre-tinned” or pre-wet with solder, applied by reflow with a flux. Pre-tinning with solder requires the component to be heated above the melting point of the solder. Some metals, such as high-strength aluminum alloys, are strengthened by cold work and heat treatment in such a way that heating even to 200° C. for 30 minutes begins to degrade the microstructure and properties, and can change (reduce or increase) the hardness by about 10% or more. These alloys should not be heated to the reflow temperature of most solders. Pre-tinning is also a poor choice for metals that diffuse rapidly in solder alloys, such as magnesium and rare-earth metals. Conventional pre-tinning is ineffective on most ceramics, even with fluxes, in that the solder does not form a chemical bond with the surface. Polymer composites and polymers often cannot be heated to solder temperature, nor solder does not adhere well to polymer surfaces.

Braze alloy layers are often adhered to components via vacuum heat treatment of slurries. This process requires a vacuum furnace and a fairly long heat cycle at a temperature well above the melting point of the braze. The long time at high temperature makes this method inappropriate for materials affected by microstructural degradation at these high temperatures, such as high-strength steel alloys. Moreover some materials, such as aluminum alloys, may melt at the high temperatures. In addition, the CTE mismatch between some ceramics and the applied braze can cause stresses in components upon cooling.

Accordingly, it would be advantageous to provide improvements to metallization methods that improve and expand the capability of reactive multilayer joining techniques for use in bonding difficult-to-wet materials and those that are temperature-sensitive. It would be further advantageous to provide joined products which are made possible by the use of reactive multilayer layer joining techniques.

### BRIEF SUMMARY OF THE INVENTION

Briefly stated, the present disclosure provides metallization methods which improve and expand the capability of reactive multilayer joining techniques to bond difficult-to-wet materials and those that are temperature-sensitive.

The present disclosure further provides improved products made possible by the improved reactive multilayer layer joining techniques.

The foregoing features, and advantages set forth in the present disclosure as well as presently preferred embodiments will become more apparent from the reading of the following description in connection with the accompanying drawings.

### BRIEF DESCRIPTION OF THE SEVERAL VIEWS OF THE DRAWINGS

In the accompanying drawings which form part of the specification:

FIG. 1 is a schematic representation of the progress of a prior art chemical reaction in a reactive multilayer foil;

FIG. 2 is a schematic representation of reactive multilayer joining technique;

FIG. 3 shows layers deposited on a component body prior to joining;

FIG. 4 shows the application of a layer onto a component body prior to joining;

FIG. 5 shows the application of an active solder to a component body;

FIG. 6 illustrates a comparison of modeled stress in a joint made by conventional reflow techniques with the stress in a joint formed using the techniques of the present disclosure;

FIG. 7 is a cross-section of a bond formed by a reactive multilayer joining technique;

FIG. 8 is an acoustic C-scan of a bond formed by a reactive multilayer joining technique;

FIG. 9 is a schematic representation of vacuum deposition using a target comprising a target plate and a backing plate bonded by the techniques of the present disclosure;

FIG. 10 illustrates two configurations in which aluminum pieces are bonded together via reactive multilayer joining techniques of the present disclosure;

FIG. 11 illustrates a thin wetting, braze, or solder layer clad onto a thicker component via a rolling process; and

FIG. 12 shows a section of a saw blade with pre-applied braze and a carbide cutting insert for joining via the reactive multilayer joining techniques of the present disclosure.

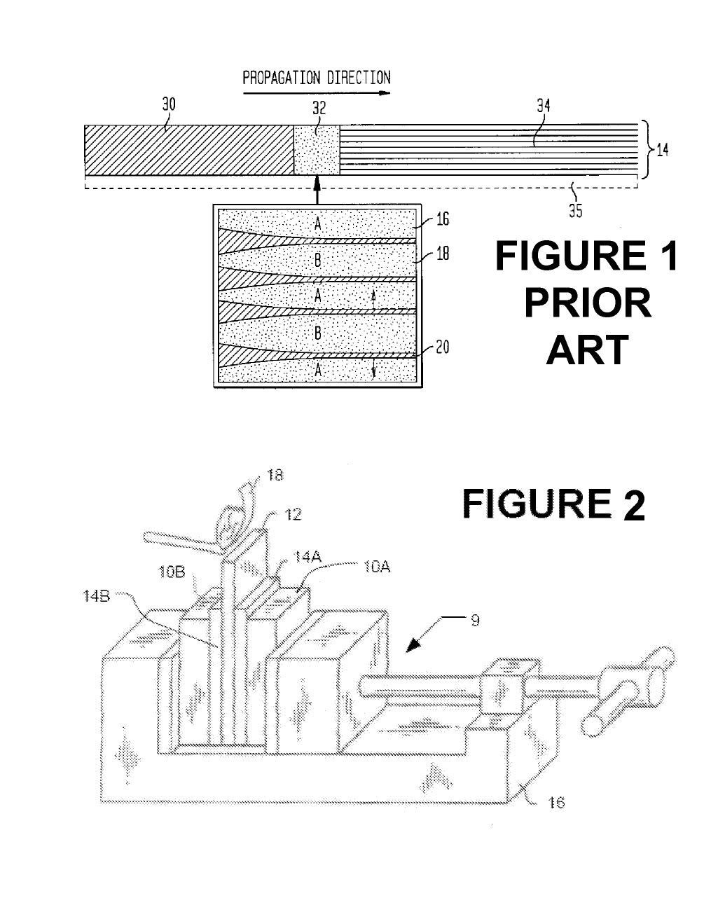

It is to be understood that these drawings are for purposes of illustrating the concepts of the invention and are not to scale.

### DETAILED DESCRIPTION OF THE INVENTION

In the reactive multilayer joining process, such as illustrated at FIG. 2, at least two component bodies 10A and 10B are bonded together using layers or sheets of solder or a braze alloy 14A and 14B and a reactive composite material (RCM) 12 such as a reactive multilayer foil. On each of the components 10A and 10B, a joining surface is prepared for adhesion by either a layer of solder or braze alloy which is pre-adhered to the joining surface, or by depositing or coating a substantially non-melting adhesion layer directly onto the joining surface. Extra solder or braze alloy in sheet form 14 may be placed against any non-melting adhesion layer or any pre-adhered solder or braze layer on the joining surfaces if desired. The RCM 12 is then placed between the components 10A and 10B, and a load (shown schematically by vise 16) is applied to press the components 10A and 10B against the RCM 12 and any solder or braze alloy sheets 14. The RCM 12 is then ignited and a chemical reaction occurs in the RCM 12 generating on the order of 20 to 200 J/cm² of heat in a fraction of a second. The RCM 12 reacts completely, at least partially melting the adjacent solder or braze layers 14A, 14B. The solder or braze 14 wets and adheres to the RCM 12, other solder or braze layers, and the prepared non-melting adhesion layer or layers, if present, or to the components 10. Upon cooling and solidification of the solder or braze alloy, the components 10 are joined. This method permits soldering or brazing of materials without significant heating of the bulk materials. Large plates bonded in this manner exhibit much lower deflection and residual stress than large plates bonded by reflow. The fine microstructures obtained in the re-solidified solder or braze due to rapid cooling after joining exhibit higher strengths than do solders or brazes after conventional reflow joining.

Ceramic and similar materials that may be bonded in this manner include (but are not limited to) aluminum oxide, quartz, indium tin oxide, boron carbide, silicon carbide, titanium carbide, tungsten carbide, silica glass, silicon, graphite, CVD diamond, aluminum nitride, silicon nitride, calcium phosphate, zinc oxide, titanium oxide, lanthanum manganese oxide, barium titanium oxide, other oxides, other carbides, and other nitrides, as well as mixtures of ceramics such as zinc oxide and aluminum oxide. Metals and alloys include, but are not limited to, lanthanum, zirconium, germanium, gold, platinum, nickel, cobalt, tungsten, titanium, copper, brass, aluminum, titanium-tungsten alloys, copper-tungsten alloys, Incusil® and other braze alloys. Solders that can be used include but are not limited to lead-tin, tin-silver, tin-zinc, and tin-silver-copper.

In a first embodiment, an adhesion layer consisting of a braze alloy is deposited onto the bonding surface of one or both components via physical vapor deposition (typically vacuum coating). Advantages of using braze alloy instead of gold include faster adhesion of other braze layers during bonding and cost. This vapor-deposited layer usually comprises two layers of different metals. A component may be vacuum coated when it cannot be directly pre-tinned with conventional solders or vacuum heat-treated with braze alloys or when it is not desirable to heat the components to the melting temperature of solders or brazes.

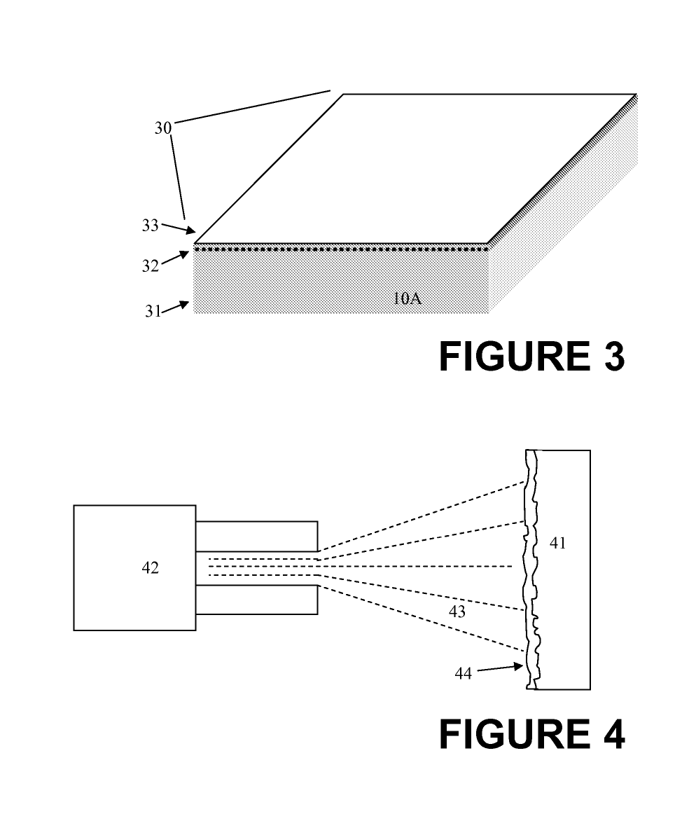

The process is performed in a vacuum chamber and consists of three steps. A schematic of a component 10A with at least one layer 30 is shown in FIG. 3. For improved adhesion of the metal layers 30 to the component 10A, the first step consists of ion cleaning the component surfaces. The second step is the deposition of a 50-500 nm thick metallic “stick” layer 32 of an element such as titanium that adheres well to most surfaces. The third step is the deposition of 1-10 μm of a braze layer 33 such as Incusil. This layer provides easy adhesion for molten solder or braze alloy but does not substantially melt during bonding. If only one component to be joined has a vapor-deposited adhesion layer, the other component to be joined may be prepared by other methods described herein or by pre-tinning with conventional solder.

Bonding of the components can be achieved in one of two ways: 1) a layer of freestanding solder sheet 14A is inserted between the braze-coated surface of the component 10A and the RCM 12 before placement of the RCM 12, optional second freestanding solder sheet 14B, and second component 10B; load application 16; and ignition 18 or 2) no freestanding solder sheet is placed between the RCM 12 and the braze-coated component 10A or 10B. The RCM 12 is furnished with a braze layer on the surface adjacent the braze-coated component. This braze layer melts and adheres to the braze layer on the component during joining.

A component with a vapor-deposited braze layer can be distinguished from components coated in other ways by virtue of having extremely uniform continuous layers that are well adhered to the component and a very thin (less than 1 μm) stick layer between the component and the outer braze layer. The grain size in all layers is typically very fine and the grains are highly oriented or textured.

For temperature-sensitive component materials, such as some aluminum alloys and some copper alloys, that cannot be heated to the melting point of solders or braze alloys, thermal spray methods are effective for deposition of thick layers with limited heating of the component. Thermal spray methods can even permit brazing of aluminum with a higher melting-point alloy. These techniques are also applicable for component materials that cannot be reflowed due to high diffusion rates into solders, such as magnesium and rare earth elements.

In a second embodiment of this invention, shown in FIG. 4, a nozzle 42 is used to spray a solder or braze alloy 43 at the bonding surface of one or both components 41 to be joined, creating a solder or braze layer 44. Any of a variety of thermal spray methods known in the art may be used, including flame spraying, arc spraying, plasma spraying, detonation spraying, high velocity oxy-fuel (HVOF) spraying, laser spraying and cold spraying. The advantage of thermally spraying a layer of solder or braze is that the component is not heated as much as in conventional pre-tinning, pre-soldering or pre-brazing methods that require the component to be heated above the melting temperature of the solder or braze. These thermal spray methods work best for metal components which can be grit blasted prior to spraying to improve the adhesion between the solder or braze layer and the component surface. Also, braze alloys tend to adhere better to components than do solder alloys in thermal spray methods.

If only one component is thermally sprayed with a layer of solder or braze, the other component may be prepared by other methods described herein, such as pre-tinning with conventional solder. Reactive multilayer joining of the components may then be carried out as described above, either with or without freestanding sheet solder 14 sandwiched between the components 10A and 10B before placement of the RCM 12, load application 16, and ignition 18. The use of sheet solder is of particular advantage when the sprayed coating is a braze alloy, which then acts as an adhesion layer for a solder bond.

In a related embodiment, a high-melting-point, hard metal such as nickel is thermally sprayed onto the component(s) to be joined. Reactive multilayer joining of the components may then be carried out as described above, either with or without freestanding sheet solder 14 sandwiched between the joining surfaces of the components 10A and 10B before placement of the RCM 12, load application 16, and ignition 18. Optionally, the hard metal-coated substrate is further coated with a layer of solder or braze alloy by any thermal spray method mentioned above before reactive multilayer joining. Hard, high-temperature metals adhere better than solder or braze alloys to substrates and have a lower tendency to clog the spray mechanism and nozzle during application. Nickel in particular is also a good non-melting layer to bond to, due to weak surface oxides and moderate thermal conductivity. The moderate thermal conductivity retains the heat from the RCM at the bonding interface longer, allowing more time for wetting than if the surface layer had a high thermal conductivity. When braze is sprayed on over the hard metal layer, the hard metal acts as an adhesion layer, helping the braze adhere to the component, and as a thermal barrier to aid wetting.

HVOF and other thermal spray techniques cause adhesion primarily through mechanical interlocking between the sprayed material and the component surface. Thus, these techniques may work better on softer component materials, such as aluminum, than on harder component materials, such as titanium or ceramics. A component with a layer of material deposited via thermal spray typically has a rough interface between the bulk and the surface layer. The roughness is due in-part to the grit blasting and the spray process. An effective grit is 60 mesh alumina, and an effective roughness may be between Rₐ=3 μm and Rₐ=20 μm (120 microinches−800 microinches). Another characteristic of thermal spray coatings is the microstructure of the coating, which retains the structure of the individual sprayed droplets or particles, but flattened and deformed by impact with the component surface. In essence, the microstructure of the hard metal or braze alloy is oriented in flattened irregular disks with their long dimension substantially parallel to the component-coating interface. The deformation or flattening varies with the technique. During reactive multilayer joining, a fraction of the thickness of the thermal spray coating may melt to bond the coating to the RCM and the other component. The fraction of the layer that does not melt should continue to exhibit the flattened microstructure created by the application of the coating.

Powdered metallic glass alloys may also be applied to a component joining surface by thermal spray techniques, and it may be possible to coat polymer matrix composites with solder, braze, or metallic glass alloys via thermal spray.

In another embodiment of the invention, a component joining surface is electroplated with nickel, by means known in the art, to produce a wetting layer on the surface. The component may then be bonded using RCM either with or without freestanding sheet solder 14 sandwiched between the components 10A and 10B before placement of the RCM 12, load application 16, and ignition 18.

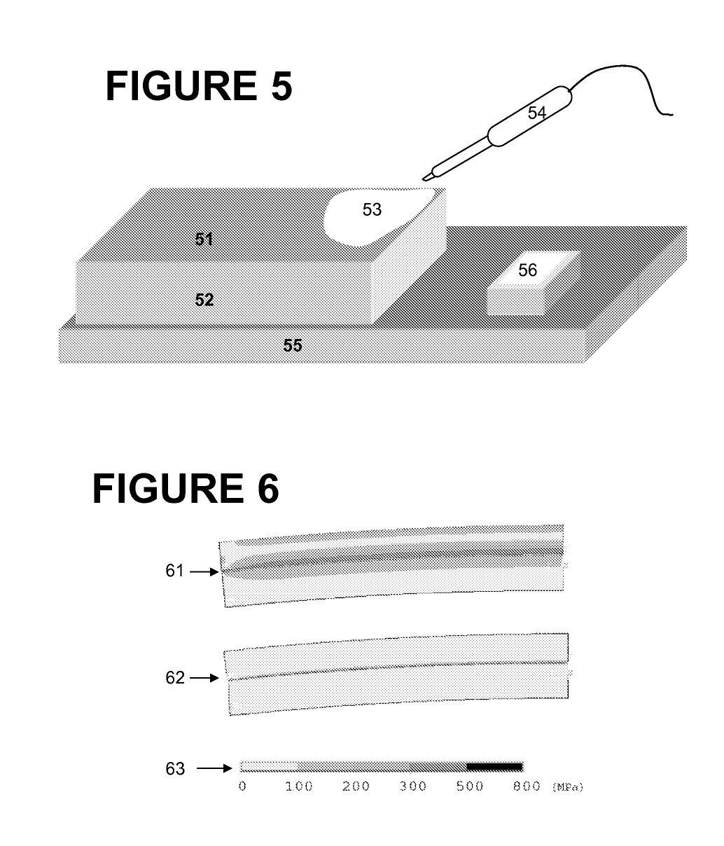

Application of solder via reflow is improved in another embodiment of the present disclosure. As shown in FIG. 5, pre-tinning with an active solder and agitation permits the adhesion of a solder layer directly to component materials that are difficult to wet. This method may be used to pre-tin components made of titanium, zirconium, magnesium, stainless steel, aluminum, graphite, tungsten, titanium-tungsten alloy, silicon, indium tin oxide, aluminum oxide, quartz, silica glass, titanium oxide, lanthanum manganese oxide, titanium carbide, boron carbide, tungsten carbide and silicon carbide and others. In this embodiment, the bonding surface 51 of one or both components 52 is pre-tinned with a layer of active solder 53, such as those sold by S-Bond Technologies LLC of Lansdale, Pa., prior to reactive multilayer joining.

Active solders are composed mostly of tin with additional alloying elements. One or more of these alloying elements are considered “active” due to high reactivity with other elements. Active alloying elements include, but are not limited to, titanium, aluminum, zinc, and rare earth elements, including cerium, erbium and lutetium. In this embodiment, active solder layers are pre-applied to components by methods of agitation. The preferred method is ultrasonic application whereby molten active solder 53 placed on the component surface 51 is agitated by means of a heated device 54 that delivers an ultrasonic pulse, usually known as an ultrasonic soldering iron, for example as described in U.S. Pat. No. 6,659,329 to Hall. Once the active solder is adhered to the surface of the component, more active solder or conventional solder with the same composition minus the active element may be used to bulk up the solder layer. After cooling, the solder layer can be milled to provide a flat surface and a layer of appropriate thickness. If only one component is pre-tinned with a layer of active solder, the other component may be prepared by previously described methods, such as pre-tinning with conventional solder. Reactive multilayer joining of the components is then carried out as described above.

Similarly, braze alloys with Ti, Zr, Cr, rare earth elements, or similar active elements may be applied to components with ultrasonic agitation. Higher temperatures are required during application due to the higher melting point of braze alloys compared with tin-based solders.

An alternative agitation method employs mechanical scrubbing, as with a metal brush submerged beneath the molten surface of the solder. This method works somewhat like flux to break up oxides on the surface of the metal. Ultrasonic agitation enables the solder to adhere to the oxide on a metal or directly to a ceramic surface. Acoustic images of the solder-component interface are more reflective when ultrasonic agitation was used than when flux or mechanical scrubbing was used, suggesting a different bond mechanism, although bond strengths are comparable.

Alternatively, prior to reactive multilayer joining, mechanical scrubbing may be used with conventional solders to assist wetting without flux. Active solders may be applied via reflow without the ultrasonic soldering iron, but some addition of energy via flux or mechanical scrubbing is needed to cause wetting and adhesion. Active solder may also be applied to a component as a flux-free slurry. The component is then vacuum heat treated at high temperature to cause reaction of the active elements with the component surface and thus bond to the component surface.

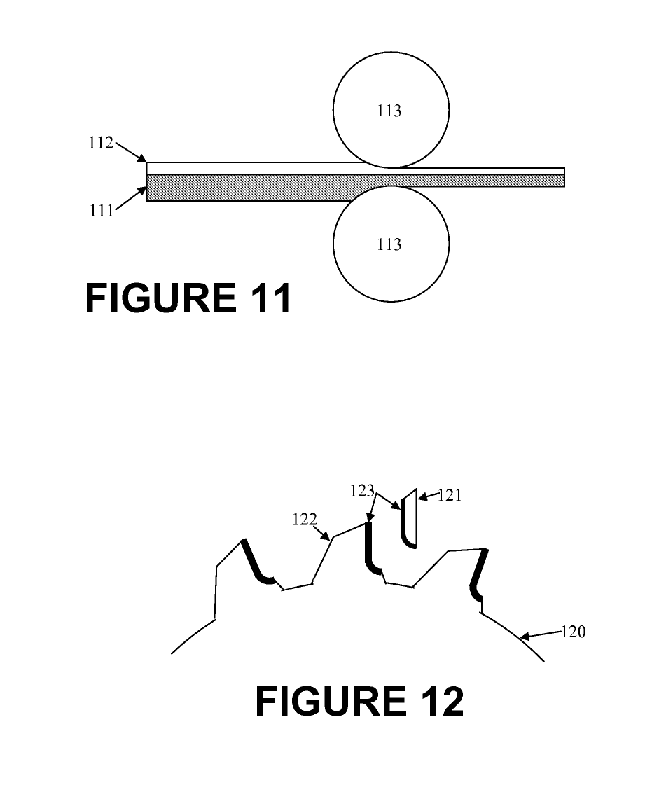

In another embodiment of the invention, shown in FIG. 11, a metal component 111 is clad with a layer 112 of a braze or solder alloy by passing the component and the braze or solder material through a rolling mill 113. The thickness of both the component and the braze or solder layer are substantially reduced in the process, preferably by at least 50%. This rolling process may introduce crystallographic texture into the microstructure of the braze or solder layer, in a manner understood in the art. Preferably, the piece is heat treated after rolling to induce some interfacial diffusion. The metal component is then bonded to another component using a reactive multilayer joining technique as described above. The portion of the braze or solder layer that does not melt during reactive multilayer joining may continue to exhibit crystallographic texture typical of rolling after the joining process.

In a further embodiment of the invention, a target plate and backing plate for vacuum sputtering are bonded using any of the above embodiments. The target plate is metallized by one of the above methods and the backing plate is either metallized as above or pretinned conventionally. Reactive multilayer joining between the target plate and the backing plate is then carried out, either with or without free-standing solder or braze alloy sheets.

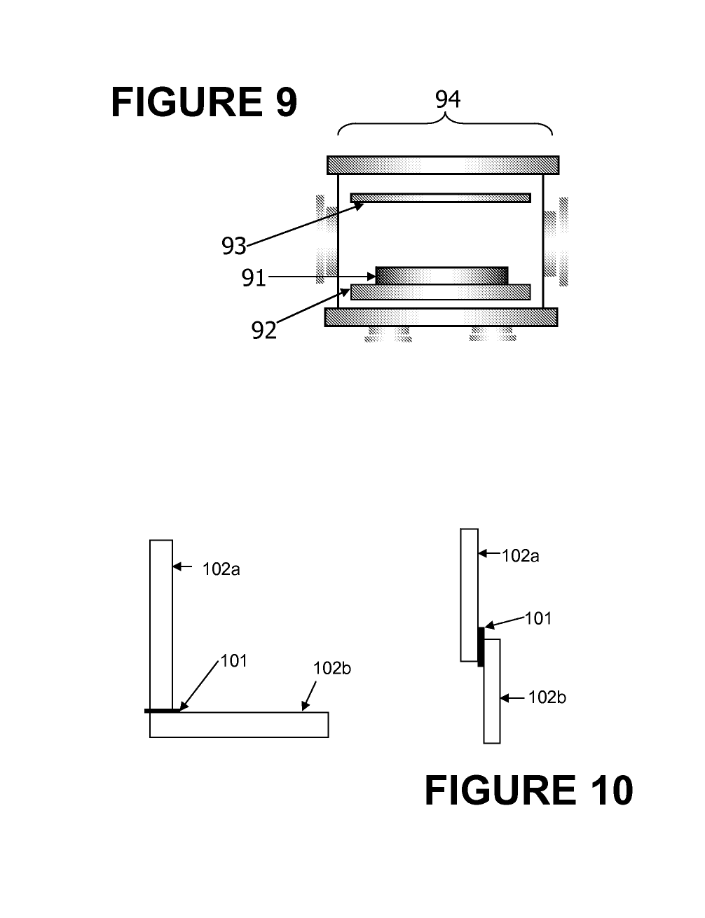

In a further embodiment, a ceramic target plate 91 and a metal backing plate 92, which are reactively joined, are employed in a vacuum sputtering machine 94, shown schematically in FIG. 9. The deposition of material from the target plate 91 onto the substrate 93 may be carried out at a high rate such that the temperature at the interface between the target plate 91 and backing plate 92 exceeds the melting point of indium. This high sputtering rate enables high throughput in the sputtering machine 94, and is possible because the target plate and backing plate are bonded using reactive multilayer joining techniques with a solder or braze having a melting point greater than that of indium. Thermal mismatch stresses are minimized between the ceramic and metal plates, reducing the likelihood of failure, and thermal transfer from the target plate to the backing plate is enhanced by the use of a solder or braze instead of an elastomer bonding agent. The ceramic target plate and backing plate may have adhesion layers applied as described in the above embodiments, or they may be more conventionally applied.

In a similar embodiment, a target plate 91 composed of a temperature-sensitive or difficult-to-wet metal or alloy reactively joined to a metal backing plate 92 as described above is used as a target in a vacuum sputtering machine 94. Temperature-sensitive metals or alloys may include metals or alloys with fine (<100 μm), very fine (<1 μm), or nano-scale (<100 nm) grain sizes, wherein the grains may grow or coarsen when exposed to heat. Other temperature-sensitive metals or alloys may exhibit rapid diffusion when heated. Currently, if a metal target material is temperature sensitive or difficult to wet, the target is often made in one piece; in essence the backing plate is manufactured from the target plate material. In these targets, expensive materials (the temperature-sensitive or hard-to-wet metals) are used to support the sputtering surface.

In contrast, with the techniques of the present invention, a target plate of an expensive sputtering material is bonded to an inexpensive backing plate, enabling cost reductions. The target plate and backing plate were joined without overheating, without damaging the temperature-sensitive target plate, and without the formation of voids in the joint due to lack of wetting. In addition, thermal transfer from the target plate 91 to the backing plate 92 is enhanced by the use of solder instead of an elastomer. The solder advantageously has a liquidus temperature greater than 200° C.

In another embodiment of the invention, examples of which are shown in FIG. 10, two components 102a, 102b made of a high-strength, age-hardened or work-hardened aluminum alloy are bonded using thermal spray and reactive multilayer joining as described above for use as part of an airplane fuselage. The strength and hardness of the individual components are changed (reduced or increased), typically by less than 10% by the joining process. For instance, Al 6061-T6 may retain its T6 temper after completion of the bonding process.

### EXAMPLE 1

### Vacuum Metallization of Vacuum Sputtering Target Plate

A 6 inch diameter lanthanum sputtering target plate was bonded to a copper backing plate. Lanthanum cannot be pre-tinned with conventional or active tin-based solders due to the high diffusion rate of lanthanum into the solder. Lanthanum diffuses easily into the solder and alters the chemistry of the solder to such an extent that the melting temperature of the solder is significantly raised. Hence, an alternative surface preparation was necessary. In this example, the lanthanum sputtering target plate was metallized by physical vapor deposition. The metallization steps were as follows:

Step 1: ion assisted plasma clean

Step 2: deposition of a 100 nm titanium stick layer

Step 3: deposition of a 3 μm thick layer of Incusil braze alloy (60% silver, 30% copper, 10% indium).

In a separate operation, a copper backing plate was pre-tinned with a layer of a conventional Sn—Ag solder alloy containing 96.5% tin and 3.5% silver. This was done by placing the copper backing plate on a hot plate and heating it to a temperature above the melting temperature of the Sn—Ag solder. Sn—Ag solder was then added to the heated surface of the copper backing plate and made to adhere to the copper surface by the introduction of acid flux. The hot plate was then allowed to cool down and the layer of Sn—Ag solder solidified. The Sn—Ag solder layer was milled to produce a flat surface layer 200 μm thick. The lanthanum sputtering target plate was then bonded to the copper plate by stacking a 50 μm thick layer of Sn—Ag solder sheet above the metallization layer on the lanthanum followed by a layer of reactive multilayer foil (RCM). Finally the backing plate was stacked above the RCM with the solder layer on the backing plate in contact with the RCM. A pressure of 3 MPa was applied. The RCM was ignited by an electric pulse simultaneously in several places around the edges of the target, reacting to melt the Sn—Ag solder sheet, which then adhered to the Incusil layer on the lanthanum target plate. On the copper side, a fraction of the Sn—Ag layer melted and adhered to the RCM. Thus, the lanthanum target plate and copper backing plate were joined.

### EXAMPLE 2

### Thermal Spray Metallization of a Temperature-Sensitive Aluminum Sputtering Target Plate

A braze bond was made between a 4 inch diameter fine-grained aluminum sputtering target plate and an aluminum backing plate. This bond is extremely challenging to achieve using conventional processes which involve heating up all or part of the fine grained aluminum sputtering target plate to a temperature equal to or above the melting temperature of the braze alloy. Herein, brazes are defined to have melting temperatures above 450° C., so heating up fine-grained aluminum to these temperatures causes unacceptable grain growth. In this example, fine-grained aluminum was coated with a 200 μm thick layer of braze alloy (60% Ag, 30% Cu, 10% Sn) by the HVOF spray process. This alloy's solidus temperature is 602° C. and its liquidus temperature is 718°, above the melting point of aluminum. During the deposition process the temperature of the fine-grained aluminum target plate remained below 150° C. and was heated for only a few minutes. Hence the heat generated in the target during the HVOF process was insufficient to cause grain growth to occur. The aluminum backing plate was prepared in the same way. Reactive multilayer joining of the fine-grained aluminum target plate to the aluminum backing plate was carried out as described above, without additional sheet solder. The RCM was a 100 μm thick Al—Ni multilayer with 3 μm Incusil on each surface. Joining was performed under a pressure of 5 MPa. During joining, the fine-grained aluminum target plate was not heated significantly so again no grain growth occurred. The net result was a braze bond between a fine-grained aluminum target plate and an aluminum backing plate that involved minimal heat during the entire process so that the fine grain structure of the target plate was kept intact. Such a bond would be impossible by conventional reflow.

### EXAMPLE 3

### Thermal Spray of Nickel Followed by Braze Alloy

A 250 μm thick layer of Ni-5Al was sprayed directly onto the joining surfaces of aluminum alloy 6061 components using wire arc spraying. Following this, a 150 μm thick layer of Silver-Copper-Tin (60Ag-30Cu-10Sn) braze powder was sprayed over the Ni-5Al bond coat layer using high velocity oxy-fuel (HVOF) spray. After spraying, the sprayed surfaces were machined flat and the thickness of the braze layer was 75 μm so that the combined sprayed layers were 325 μm thick. The sprayed faces of two components 0.75 inches×0.5 inches in area were then placed together with a piece of 100 μm thick Al—Ni RCM with 3 μm Incusil on each surface between them, 5 MPa of pressure was applied, and the reaction in the RCM was initiated to bond the components. The bonds were then broken in shear to measure the bond shear strengths, as reported in Table I.

TABLE I
Nickel and braze layers applied via thermal spray

| | RCM | |
|---|---|---|
| | Thickness | Bond shear |
| Thermal Spray Method | (μm) | strength (MPa) |
| Ni Arc spray, Braze HVOF spray | 80 | 50 |
| Ni Arc spray, Braze HVOF spray | 100 | 48 |
| Ni Arc spray, Braze HVOF spray | 150 | 42 |
| Ni Arc spray, Braze HVOF spray | 200 | 52 |

### EXAMPLE 4

### Thermal Spray of Nickel

A 375 μm thick layer of Ni-5Al was sprayed directly onto the surfaces of aluminum alloy 6061 components using wire arc spraying. The sprayed surfaces were then machined flat leaving a Ni-5Al layer 125 μm thick. The sprayed faces of two components 0.75 in×0.5 inches in area were then placed together with a piece of 100 μm thick Al—Ni RCM with 3 μm Incusil on each surface between them, 5 MPa of pressure was applied, and the reaction in the RCM was initiated to bond the components. The bonds were then broken in shear to measure the bond shear strengths, as reported in Table II.

TABLE II
Nickel layer applied via thermal spray

| Thermal Spray | RCM | Bond shear |
|---|---|---|
| Method | Thickness (μm) | strength (MPa) |
| Arc spray | 80 | 46 |
| Arc spray | 100 | 50 |
| Arc spray | 150 | 47 |
| Arc spray | 200 | 46 |

### EXAMPLE 5

### Electroplating with Nickel

A braze bond was made between a 4 inch diameter fine-grained aluminum sputtering target plate and an aluminum backing plate. The two aluminum plates were electroplated with 80 μm of nickel. Reactive multilayer joining of the two aluminum plates was carried out as described above, without additional sheet solder. The RCM was a 200 μm thick Al—Ni multilayer with 6 μm Incusil on each surface. Joining was performed under a pressure of 5 MPa. During joining, the fine-grained aluminum target plate was not heated significantly so no grain growth occurred. The net result was a braze bond between a fine-grained aluminum target plate and an aluminum backing plate that involved minimal heat during the entire process so that the fine grain structure of the target plate was kept intact.

### EXAMPLE 6

### Pre-Tinning with Active Solder and Ultrasonic Agitation

A 57″×9″ titanium carbide sputtering target plate, pre-tinned with a layer of active tin solder, was bonded to a copper backing plate. For pre-tinning (FIG. 5), the titanium carbide plate 52 was placed on a hot plate 55 and heated above the melting temperature of the active solder. The active solder was melted in a separate crucible 56 placed on the hot plate or in a separate solder melting pot. An ultrasonic soldering iron 54 was heated above the melting temperature of the active solder by means of its own heating coil. The tip of the heated ultrasonic soldering iron was then dipped into the molten active solder and applied to the heated ceramic target plate to transfer molten active solder to the target plate. The heated ultrasonic soldering iron 54 was made to vibrate at an ultrasonic frequency while in contact with the pool of molten solder 53 on the surface 51 of the titanium carbide plate 52. In this way a layer of active solder was made to adhere to the surface of the ceramic plate. More molten active solder was then transferred to the target plate and the process was repeated until the entire surface area of the titanium carbide plate was coated with a layer of active solder. The hot plate was then allowed to cool down and the layer of active solder solidified. The solder was then milled to provide a flat layer 200 μm thick. In a separate operation the copper backing plate was pre-tinned with a layer of conventional solder alloy, 96.5% tin 3.5% silver, as described in Example 1. The titanium carbide plate was then bonded to the copper plate by inserting a layer of reactive multilayer foil (RCM) between the pre-wet bonding surfaces. Pressure of 1 MPa was applied, and the RCM was ignited with an electric pulse. The RCM reacted completely, melting the surfaces of both solder layers such that they adhered to the RCM and each other (through cracks in the RCM). Thus, the titanium carbide target plate and copper backing plate were joined.

### EXAMPLE 7

### Pre-Tinning Via Scrubbing

Two titanium plates were pre-tinned with an active solder on a hot plate by scrubbing with a wire brush. The process may be done either under nitrogen or in air but with copious amounts of solder such that the bare titanium metal exposed by the brush is perpetually covered by solder. The solder was then milled flat and the titanium plates were bonded using reactive multilayer joining as described above.

### EXAMPLE 8

### Residual Stress Analysis

Finite Element Modeling (FEM) of the bonding of a ceramic (B₄C) target plate to a metal (Cu—Cr) backing plate was performed. The geometry consisted of a 6″×6″×0.25″ B₄C target plate bonded with 96.5Sn-3.5Ag solder to a 6″×6″×0.31″ Cu—Cr plate. Two separate cases were analyzed. The first case was a conventional bonding operation where the entire assembly was heated uniformly above the melting temperature of the solder and then cooled uniformly with a bond forming once the solder solidified (below 221° C.). The second case was a bonding operation using reactive multilayer foil as a heat source with non-uniform heating and cooling of the solder and the components. A cross-sectional temperature profile captured at the moment of solder solidification was first generated by independent finite difference modeling and used as an input for the FEM analysis. The residual stress, expressed as the von Mises stress, after both these bonding operations is represented in FIG. 6. The residual stresses in the components and at the bond line are about an order of magnitude lower for the bonding operation using reactive multilayer foil 62 compared to the conventional bonding operation 61, as shown by scale 63. In fact, the predicted residual stresses for the conventional bonding operation 61 suggest that a conventional bond between these two components would not be possible, as is found in practice.

### EXAMPLE 9

### Bond Strength

The bond strengths of various configurations joined with reactive multilayer foil have been measured. Table III lists shear strengths measured in bonds with different solders. The measured strengths are found to depend on the strength of the solder used and not on the combination of materials bonded. Hence bonds using indium solder are limited in strength by the strength of indium to 4-6 MPa (580-870 psi), while bonds formed with Sn—Ag measure 23-28 MPa (3335-4060 psi) due to the higher strength of Sn—Ag solder. In addition, where it is possible to form conventional reflow bonds because of low CTE mismatch between the two components, the measured strengths of such bonds are generally about 10% lower than the bonds formed with reactive multilayer foil techniques. The higher strength of reactive multilayer foil bonds can be attributed to the refined microstructure formed due to the rapid cooling during bonding with reactive multilayer foil.

TABLE III
Measured shear strength of bonds formed using reactive
multilayer foil for different solder and braze alloys:

| | Reactive multilayer | Conventional |
|---|---|---|
| Solder/Braze | foil bonds (MPa) | reflow bonds (MPa) |
| In | 4-6 | 2-3 |
| Sn—Pb | 17-20 | |
| Sn—Ag | 23-28 | 19-24 |
| Sn—Ag—Sb | 55-65 | |
| Incusil ® | 25-120 | |

### EXAMPLE 10

### Bond Quality

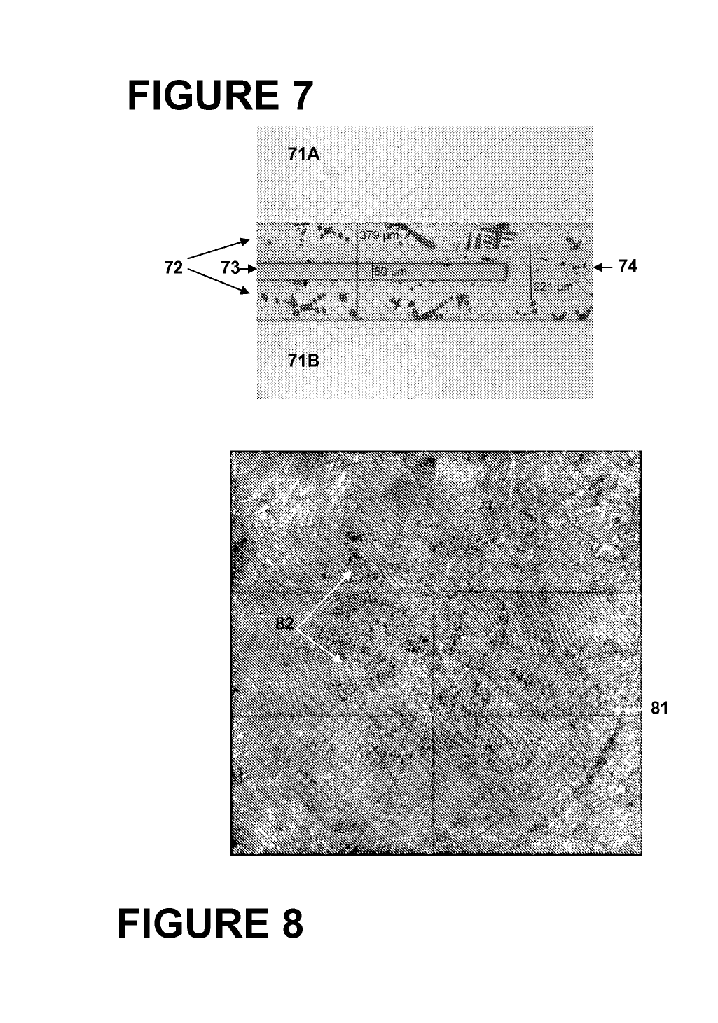

The quality of large area reactive multilayer bonds, up to 300 square inches in area, has been found to be consistently very good and beyond the capability of current commercial processes. For any combination of components and solder, the required thickness and properties of the multilayer foil can be chosen to ensure that sufficient heat is transferred into the solder for melting, without heating the components significantly above room temperature. FIG. 7 illustrates a cross section of a bond between two brass discs 71A and B (8 in. diameter) achieved by melting 63Sn-37Pb solder 72 with reactive multilayer foil 60 μm (0.0024 in) thick 73. For this bond the 63Sn-37Pb solder layers 72 were pre-applied by conventional reflow to the components 71A and B and milled back to thicknesses of approximately 150 μm (0.006 in). FIG. 7 illustrates good wetting between the reactive multilayer foil 73 and the solder 72 and between the solder 72 and components 71A and B with no voids observable. Furthermore, it is apparent that the reactive multilayer foil 73 does not form a continuous layer, but rather breaks up during bonding with the gaps 74 filled in by the molten solder. This results in a reinforced composite material containing hard long particulates, the intermetallic product of the reactive multilayer foil, in a ductile matrix, the solder.

The percentage bond coverage of sputter target plates, including ceramic target plates, bonded to backing plates using reactive multilayer foils exceeds the standard industry requirements of total coverage greater than 95%, no single void greater than 2% and no edge voids. The typical coverage for reactive multilayer foil bonds is greater than 98%. FIG. 8 shows an ultrasonic scan of the bond surface of a 12 in×12 in titanium alloy target plate (CTE=8.6 μm/m/° C.) bonded with reactive multilayer foil to an aluminum backing plate (CTE=23.6 μm/m/° C.). Both plates were pre-wet with active tin solder and mechanical agitation. The bond coverage is measured to be greater than 99% without any edge voids, thus exceeding the current industry standard. Various dark lines can be observed in the scan. The non-straight dark lines 81 are caused by cracks in the reactive multilayer foil that are filled in with solder, similar to the gap 74 shown in FIG. 7. The straight dark lines 82 indicate that multiple pieces of reactive multilayer foil were used to achieve complete coverage of the bond area.

### EXAMPLE 11

### Boron Carbide Targets Joined by Reactive Multilayer Joining and Conventional Joining

A boron carbide (B₄C) sputtering target plate bonded to a copper-chromium alloy backing plate with reactive multilayer joining using 96.5Sn-3.5Ag solder was compared to a similar B₄C target plate and backing plate bonded commercially with indium. In both cases the bonded target was a 4-piece construction of 0.25 inch thick rectangular B₄C tiles bonded to a single backing plate. Each B₄C tile measured 6.25 inches long and 6 inches wide so that the total bond area was 25 inches long and 6 inches wide. The B₄C target plate bonded with reactive multilayer joining was prepared with physical vapor deposition of a titanium stick layer and an Incusil wetting layer. The backing plate was conventionally pre-tinned with flux on a hot plate. A freestanding layer of 96.5Sn 3.5Ag solder alloy was placed between the metallization layer on the B₄C tiles and the reactive multilayer foil during bonding. The commercial bond was made by conventional indium reflow.

The two B₄C targets were evaluated by DC magnetron sputtering in identical cathodes in the same vacuum chamber. All sputtering parameters, except for power input, were also identical. The conventionally bonded target was run at 2 kW, while the target bonded with reactive multilayer foil was run at 4 kW. A summary of each target's performance is given in Table IV below. The conventionally bonded target cracked after the first use, after less than 10 hours. After continued use for about 100 hours, one of the B₄C tiles debonded from the backing plate. The target that was bonded using reactive multilayer joining was run at twice the power in multiple uses in excess of 200 hours with no evidence of cracking or debonding. The significantly better performance of the reactively bonded target can be attributed to two main factors. First, the reactive multilayer bonding operation imparted very little residual stress to the bond and the components and thus lowered the driving force for cracking during use. Second, a higher melting temperature solder was used. The 96.5Sn-3.5Ag solder melts at 221° C., compared to 157° C. for indium solder. This means that the bond can tolerate higher temperatures generated at higher input powers. It is the reactive multilayer bonding that enables the use of 96.5Sn-3.5Ag solder.

TABLE IV
Performance Summary of Boron Carbide Targets

| | Max. Power | Power at | Max. Power | Sputtering |
|---|---|---|---|---|
| | without | Failure | Density | Rate |
| Bond Type | Failure (W) | (W) | (W/cm²) | (μm/hr) |
| Conventional | 2000 | 2000 | 2 | 1.1 |
| Indium | | | | |
| Reactive multilayer | 4000 | Not run to | 4 (at least) | 2.3 |
| joining | | failure | | |

### EXAMPLE 12

### Indium Tin Oxide

Four identical indium tin oxide (ITO) sputtering target plates (7.6 cm diameter) were bonded to copper backing plates using four different bonding processes:

(1) Conventional reflow of In—Sn solder;

(2) Conventional reflow of In solder;

(3) Elastomer bonding; and

(4) Pre-tin with active Sn—Ag solder and ultrasonic agitation, followed by reactive multilayer joining as in the present invention.

The bonded ITO targets were then run sequentially in the same magnetron cathode under DC power. The power was ramped up in increments, holding for a minimum of 1 hour at each power setting to observe stable sputtering performance. A summary of each target's performance is given in Table V below.

The target bonded with In—Sn solder (Tₘ=118° C.) using a conventional reflow process failed while ramping from 200 W to 300 W, when the In—Sn solder melted and dripped out of the bond, thereby shorting to the anode. Thus the maximum sustainable power recorded for this target was 200 W. Similarly, the conventionally reflowed indium solder (Tₘ=157° C.) bonded target was stable at 325 W and failed at 425 W.

The target bonded with elastomer began to exhibit small cracks when the power was ramped from 200 W to 300 W, but remained relatively stable operating at 300 W. However, as soon as the power was ramped from 300 W to 400 W, the cracks became larger, and current and power readings failed to stabilize. Eventually, pieces of the target plate detached from the backing plate. Thus, the maximum sustainable power recorded for this target was 300 W.

Two ITO/copper targets bonded with active Sn—Ag solder (Tₘ=221° C.) and reactive multilayer joining techniques of the present invention were also tested. The first was run in an argon atmosphere and the power was ramped up in large increments. It was stable at 400 W but failed due to solder melting when ramping to 500 W. The second test was run in an argon-2% oxygen atmosphere to better simulate likely operating conditions. The power was ramped fairly rapidly to 460 W and held for 12 hours. The power was then ramped in 20 W increments to failure at 540 W. Thus the reactively bonded targets withstood the highest sputtering power using the highest melting temperature solder. In addition, the reactive multilayer bond has better thermal conductivity than the elastomer bond.

TABLE V
Performance Summary of ITO targets

| | | Max. Power | Power at | Max. Power |
|---|---|---|---|---|
| | | without | Failure | Density |
| Bond Type | Atmosphere | Failure (W) | (W) | (W/cm²) |
| Conventional | Argon | 200 | 300 | 4.4 |
| (In—Sn) | | | | |
| Conventional | Argon - 2% | 325 | 425 | 7.2 |
| (In) | Oxygen | | | |
| Elastomer | Argon | 300 | 424 | 6.6 |
| NanoBond ® | Argon | 400 | 500 | 8.8 |
| (Sn—Ag) | | | | |
| NanoBond ® | Argon - 2% | 460 (12 hrs) | 540 | 10.1 |
| (Sn—Ag) | Oxygen | | | |

### EXAMPLE 13

### Alumina

Two identical alumina (Al₂O₃) sputtering target plates (7.6 cm diameter) were bonded to copper backing plates using two different bonding processes:

(1) Elastomer bonding; and

(2) Pre-tinning with active Sn—Ag solder and ultrasonic agitation, followed by reactive multilayer joining as in the present invention.

The two bonded alumina targets were then run sequentially in the same magnetron cathode under RF power. The power was ramped up in 100 W increments, holding for a minimum of 1 hour at each power setting to observe stable sputtering performance. A summary of each target's performance is given in Table VI below. The target bonded with the elastomer started to crack at 300 W, but seemed to remain stable at this power. However, when the power was ramped to 400 W pieces of the target detached from the backing plate. The target bonded by reactive multilayer joining performed better and was very stable at 400 W.

TABLE VI
Performance summary of alumina targets

| | Max. power | Power at | Max. Power |
|---|---|---|---|
| Bond Type | without failure (W) | Failure (W) | Density (W/cm²) |
| Elastomer | 300 | 400 | 6.6 |
| Reactive | 400 | Not run to | 8.8 (at least) |
| multilayer joining | | failure | |

### EXAMPLE 14

### High-Strength Aluminum

Aluminum coupons were coated with Sn—Ag—Cu solder using arc-spray or with CuSilTin braze alloy using arc-spray, plasma spray or high-velocity oxyfuel spray (HVOF), then bonded together using reactive multilayer foil without the addition of free-standing sheet solder. Measured shear strengths are reported in Table VII. The best strengths were obtained with HVOF. In another experiment, aluminum was cold-sprayed with nickel prior to pre-wetting conventionally with Sn—Ag solder and reactive multilayer bonding. The resulting shear strength was about 15 MPa (2200 psi).

TABLE VII
Shear strengths obtained with thermal spray
and reactive multilayer joining

| | | | | Braze | |
|---|---|---|---|---|---|
| | | | | cladding | |
| | | | | on | |
| | | Coating | Reactive | reactive | Shear |
| | Material | Thickness | Foil | foil | Strength |
| Process | Sprayed | (μm) | (μm) | (μm) | (MPa) |
| Arc Spray | Sn—Ag—Cu | 200 | 80 | 1 | 10.00 |
| | solder | | | | |
| Arc Spray | CuSilTin | 200 | 100 | 6 | 15.33 |
| Plasma | CuSilTin | 200 | 100 | 6 | 13.33 |
| HVOF | CuSilTin | 350 | 100 | 6 | 17.37 |
| (Wire) | | | | | |
| HVOF | CuSilTin | 200 | 100 | 6 | 26.00 |
| (Powder) | | | | | |

### EXAMPLE 15

### Cladding of Aluminum with Braze Alloy

A strip of aluminum 0.25″ thick and 2″ wide is mechanically cleaned and placed against a mechanically cleaned strip of copper-silver-tin braze alloy 0.005″ thick. The two strips are heated to approximately 50-60° C. before passage through a 4-hi rolling mill with warm (50-60° C.) rolls. Upon exiting, the strips are found to be mechanically bonded and reduced in thickness by about 50%. The resulting clad strip is then heat treated at about 300° C. under nitrogen for up to one half hour to cause some interdiffusion and formation of a chemical (metallurgical) bond before bonding with reactive multilayer joining.

### EXAMPLE 16

### Carbide Inserts and Heat-Treated Steel

Steel cutting tools are often made from specific steel alloys that are carefully heat-treated to maximize toughness. Carbide inserts are brazed to the tools to provide cutting surfaces. In order to braze the carbide inserts to the steel, an induction or torch heating method is commonly used. These methods can overheat the steel far from the braze location, degrading the microstructure and reducing desired properties. A steel cutting tool, such as a saw blade 120 having teeth 122 shown schematically in FIG. 12, may have braze alloy 123 pre-applied by thermal spray methods. The carbide insert 121 (with braze alloy pre-applied by other means) may then be attached to the saw tooth 122 with a reactive multilayer joining technique of the present invention, providing strength as high as the strength of the bond at the pre-applied braze-steel interface.

### EXAMPLE 17

### Metallic Glass

Thermal spray techniques could be used to apply metallic glass alloys to substrates in the same way that solder and braze alloys are applied. Reactive multilayer joining techniques of the present invention may then used to bond components with metallic glass layers.

### EXAMPLE 18

### Polymer-Matrix Composites

Thermal spray techniques may be used to apply solder or braze alloys to polymer-matrix composites. Reactive multilayer joining techniques of the present invention are then used to bond the polymer-matrix composite components.

It can now be seen that one aspect of the invention provides a method of bonding a first component body to at least an additional component body comprising the steps of metallizing the bonding surface of at least one of the component bodies; disposing at least one layer or sheet of reactive composite material and at least one layer or sheet of solder or braze between the component bodies; applying pressure on the layer of reactive composite material through the component bodies; and initiating an exothermic reaction in the layer of reactive composite material to form a bond between the component bodies. The term “disposing” as used herein thus includes precoating a layer on a component or on a sheet of reactive composite material, solder or braze. The step of metallizing may comprise ion cleaning and at least one step of vapor deposition of a braze alloy, thermal spray application of a hard metal, braze, or solder alloy, electroplating, ultrasonic application of an active solder alloy, brushing of the bonding surface, as with a wire brush under molten solder, or cladding of the joining surface with a solder or braze alloy.

A second aspect of the invention provides a method of making a target for vapor deposition on a substrate comprising the steps of providing at least one target plate comprising material to be vapor deposited and a backing plate; metallizing the target plate; disposing a layer of reactive composite material between the target plate and the backing plate; disposing at least one layer of solder or braze between the target plate and the backing plate; applying pressure on the layer of the reactive composite material; and initiating an exothermic reaction in the layer of reactive composite material to bond the target plate to the backing plate.

In a third aspect, the present invention provides a method of vapor deposition of target material onto a substrate comprising the steps of providing a target comprising a target plate that has been bonded to a backing plate by an exothermic reaction in a layer of reactive composite material (i.e. the target plate is joined to the backing plate by a bonding layer that includes the reaction remnants of a reactive composite material); installing the target in a deposition chamber; evacuating the deposition chamber; and vapor depositing material from the target plate onto the substrate. The bonding layer consists of a layer of solder or braze alloy with a liquidus temperature greater than 200° C. Preferably, the interface between the target plate and the bonding layer has an average roughness between 3 and 20 μm and a fraction of the microstructure of the bonding layer comprises flattened irregular disks with their long dimension oriented substantially parallel to the interface between the target plate and the bonding plate. Alternatively, the target plate material comprises a temperature-sensitive alloy such that a physical property of the target plate material changes by at least 10% when held above the liquidus temperature of the solder for thirty minutes or more.

Other embodiments of the present invention include the apparatus of improved vapor deposition targets manufactured by the above-described methods.

Further embodiments of the present invention include the apparatus of improved joints and bonded objects made using the bonding method described. Such joints and bonded objects may include, inter alia, parts of airplane fuselage and cutting tools such as saw blades. These objects include joined components with bond regions comprising reaction remnants of a reactive composite material adhered to a layer of braze, solder, or metallic glass alloy which was applied via thermal spray, so that the joining surface of at least one of the components has an average roughness between 3 and 20 μm.

Another embodiment of the present invention is an object comprising at least two bonded components wherein one of the components comprises a polymer-matrix composite with its joining surface coated with a braze or solder alloy and reaction remnants of a reactive composite material adhered to the braze or solder alloy.

Another embodiment of the present invention is an object comprising at least two bonded components wherein one of the components comprises a temperature-sensitive aluminum alloy. The joining surface of the aluminum alloy may be coated with a braze alloy that melts at a temperature above the melting point of the aluminum alloy, or the joining surface of the aluminum alloy may be coated with a solder with liquidus temperature greater than 200° C.

Another embodiment of the present invention consists of an object comprising at least two components bonded with solder and reaction remnants of a reactive composite material, wherein at least one of the component comprises material that is temperature-sensitive.

Another embodiment of the present invention consists of an object comprising at least two bonded components wherein an active solder alloy is adhered to the joining surface of at least one of the components, and the bond region comprises reaction remnants of a reactive composite material. In particular, one of the components may comprise a ceramic.

As various changes could be made in the above constructions without departing from the scope of the disclosure, it is intended that the processes and products set forth in the description or shown in the accompanying drawings shall be considered as illustrative and not limiting.

1. A method for bonding a bonding surface of a first component body to a bonding surface of at least one additional component body, comprising the steps of:
metallizing the bonding surface of at least one of the component bodies;
disposing a reactive composite material and a solder or braze between the bonding surfaces of the component bodies;
applying pressure on the reactive composite material through the component bodies; and
initiating an exothermic reaction in the reactive composite material to form a bond between the bonding surfaces of the first component body and the at least one additional component body.

2. The method of claim 1 wherein said step of metallizing comprises ion cleaning and the vapor deposition of a braze alloy onto the bonding surface.

3. The method of claim 1 wherein said step of metallizing comprises thermal spray application of a metal or metal alloy onto the bonding surface.

4. The method of claim 1 wherein said step of metallizing comprises ultrasonic application of an active solder or active braze alloy onto the bonding surface.

5. The method of claim 1 wherein said step of metallizing comprises applying a molten solder to the bonding surface and brushing the bonding surface with a wire brush under said molten solder.

6. The method of claim 1 wherein said step of metallizing comprises cladding the bonding surface with a metal.

7. A product of a first component body and at least one additional component body bonded together by the method of claim 1.

8. A method of vapor deposition onto a substrate comprising the steps of:
providing a target plate bonded to a backing plate with a bond comprising the reaction remnants of a reactive composite material;
installing the target plate and bonded backing plate in a vacuum deposition chamber; and
vapor depositing material from the target plate onto the substrate.

9. A method of vapor deposition on a substrate comprising the steps of:
providing a target comprising a target plate with a joining surface bonded at an interface by a layer of solder or braze alloy to a backing plate, said interface between said joining surface and said layer of solder or braze alloy having an average roughness between 3 and 20 μm, and wherein said bonding layer comprises the reaction remnants of a reactive composite material;
installing the target in a vacuum deposition chamber; and
vapor depositing material from the target plate onto the substrate.

10. The method of claim 9 wherein a fraction of a microstructure of the solder or braze alloy closest to the backing plate comprises flattened irregular disks having long dimensions which are substantially parallel to said interface

11. The method of claim 8 wherein said bonding layer further comprises an active solder or active braze.

12. A method of vapor deposition onto a substrate comprising the steps of:
providing a backing plate and at least one target plate;
metallizing the target plate;
disposing at least one layer of reactive composite material and at least one layer of solder or braze between the backing plate and the target plate;
applying pressure on the sheet of reactive composite material through the backing plate and the target plate;
initiating an exothermic reaction in the sheet of reactive composite material to form a bond between the backing plate and the target plate;
installing the target plate and the bonded backing plate in a vacuum deposition chamber; and
vapor depositing material from the target plate onto the substrate.

13. The method of claim 12 wherein the step of metallizing comprises ion cleaning and the vapor deposition of a braze alloy onto said target plate.

14. The method of claim 12 wherein the step of metallizing comprises thermal spraying of a metal or metal alloy onto said target plate.

15. The method of claim 12 wherein the step of metallizing comprises ultrasonic application of an active solder onto said target plate.

16. The method of claim 12 wherein the step of metallizing comprises cladding the target plate with a metal.

17. A product made by the vapor deposition method of claim 12.

18. A vapor deposition target comprising a target plate bonded to a backing plate wherein a bond region between said target plate and said backing plate comprises the reaction remnants of a reactive composite material.

19. The vapor deposition target of claim 18 wherein the target plate comprises a ceramic material.

20. The vapor deposition target of claim 18 wherein the target plate comprises a material selected from the group consisting of indium-tin-oxide, silicon dioxide, aluminum oxide, titanium oxide, lanthanum manganese oxide, calcium phosphate, barium titanium oxide, zinc oxide, aluminum nitride, silicon nitride, boron carbide, titanium carbide, tungsten carbide, and silicon carbide.

21. The vapor deposition target of claim 18 wherein the target plate comprises a temperature-sensitive material.

22. The vapor deposition target of claim 21 wherein the temperature-sensitive material has an average grain size of less than 100 μm.

23. The vapor deposition target of claim 21 wherein the temperature-sensitive material has an average grain size of less than 1 μm.

24. The vapor deposition target of claim 21 wherein the temperature-sensitive material has an average grain size of less than 100 nm.

25. The vapor deposition target of claim 18 wherein said bond region further includes an active solder.

26. The vapor deposition target of claim 25 wherein said active solder comprises tin and an element selected from the group of elements consisting of titanium, aluminum, zinc, and rare earth.

27. The vapor deposition target of claim 18 wherein the bond region further includes an active braze.

28. The vapor deposition target of claim 27 wherein the active braze comprises an element selected from a group of elements including titanium, zirconium, chromium, and rare earth elements.

29. A section of airplane fuselage comprising at least two aluminum components joined at a bond region which includes reaction remnants of a reactive composite material.

30. A cutting tool comprising a steel component and at least one carbide component joined at a bond region which includes the reaction remnants of a reactive composite material.

31. A bonded object comprising at least a first component with at least one joining surface coated with a layer of metal or metal alloy, wherein the joining surface has an average roughness between 3 and 20 μm, and wherein reaction remnants of a reactive composite material are adhered to the opposite surface of the layer of metal or metal alloy on the joining surface of the first component; and
at least a second component having a second joining surface adhered to the remnants of the reactive composite material to form a bond with said first component.

32. The bonded object of claim 31 wherein a fraction of the microstructure of the metal or metal alloy closest to the joining surface of the first component comprises flattened irregular disks having long dimensions which are substantially parallel to the interface.

33. The bonded object of claim 31 wherein the layer of metal or metal alloy comprises a metallic glass alloy.

34. An object comprising:
at least a first component including a polymer-matrix composite with at least one joining surface coated with a layer of metal or metal alloy;
reaction remnants of a reactive composite material adhered to the layer of metal or metal alloy on the joining surface of the first component; and
at least a second component with at least one joining surface adhered to the remnants of the reactive composite material.

35. An object comprising:
at least a first component including an aluminum alloy with at least one joining surface coated with a layer of braze alloy, wherein the braze alloy has a melting temperature above the melting temperature of the aluminum alloy;
reaction remnants of a reactive composite material adhered to the braze alloy on the joining surface of the first component; and
at least a second component with at least one joining surface adhered to the remnants of the reactive composite material.

36. An object comprising:
at least a first component including a material with at least one joining surface coated with a layer of solder;
reaction remnants of a reactive composite material adhered to the solder on the joining surface of the first component; and
at least a second component with at least one joining surface adhered to said remnants of a reactive composite material,
wherein the material of the first component is temperature-sensitive.

37. The object of claim 36 wherein the temperature-sensitive material comprises an aluminum alloy.

38. The object of claim 36 wherein a structural physical property of the temperature-sensitive material alters by at least 10% responsive to the temperature-sensitive material being maintained above the liquidus temperature of the solder for at least 30 minutes.

39. An object comprising:
at least a first component with at least one joining surface coated with a layer of an active solder or active braze alloy;
reaction remnants of a reactive composite material adhered to the layer of solder or active braze alloy on the joining surface of the first component; and
at least a second component with at least one joining surface adhered to said reaction remnants of a reactive composite material.

40. The object of claim 39 wherein the active solder or active braze alloy contains an active element chosen from the group consisting of titanium, aluminum, zirconium, chromium, zinc, and rare earth elements.

41. The object of claim 39 wherein the first component comprises a ceramic.
